(19) United States
(12) Patent Application Publication
(10) Pub. No.: US 2026/0117103 A1
(43) Pub. Date: Apr. 30, 2026

(54) DISPLAY APPARATUS, ELECTRONIC DEVICE, AND METHOD OF MANUFACTURING DISPLAY APPARATUS

(71) Applicant: Samsung Display Co., Ltd., Yongin-si (KR)

(72) Inventors: JOOSUB LEE, Yongin-si (KR); YOUNGJU PARK, Yongin-si (KR); Seongsoo Yoo, Yongin-si (KR); SANGWON EUN, Yongin-si (KR); JINYOUNG LEE, Yongin-si (KR)

(21) Appl. No.: 19/371,981

(22) Filed: Oct. 28, 2025

(30) Foreign Application Priority Data
Oct. 29, 2024 (KR) 10-2024-0150094

(51) Int. Cl. C09J 133/04; B32B 7/12; B32B 17/06; H05K 5/03

(52) U.S. Cl. CPC C09J 133/04; H05K 5/03; B32B 7/12; B32B 17/06; B32B 2457/20

(57) ABSTRACT

Provided is a display apparatus including a display module that emits visible light, a window member opposite to one surface of the display module, and an adhesive layer between the display module and the window member, wherein the adhesive layer is formed by curing an adhesive including at least a high-molecular weight acrylic polymer having a first weight-average molecular weight of at least 700,000 and a low-molecular weight acrylic polymer having a second weight-average molecular weight of less than 500,000, the adhesive layer has a stress relaxation value of 0.01 to 0.07 before curing, and a stress relaxation value of 0.30 to 0.50 after curing, and an amount of the high-molecular weight acrylic polymer is at least 30 parts by weight, with respect to 100 parts by weight of a sum of an amount of the high-molecular weight acrylic polymer and an amount of the low-molecular weight acrylic polymer.

### CROSS-REFERENCE TO RELATED APPLICATION

The present application claims priority to and the benefit of Korean Patent Application No. 10-2024-0150094, filed on Oct. 29, 2024, in the Korean Intellectual Property Office, the entire content of which is hereby incorporated by reference.

### BACKGROUND

### 1. Field

One or more embodiments of the present disclosure relate to a display apparatus, an electronic device, and a method of manufacturing the display apparatus.

### 2. Description of the Related Art

Electronic devices, such as smartphones, tablet PCs, digital cameras, laptop computers, navigators, and smart televisions, which provide images to users, include display apparatuses to display the images. A display apparatus includes a display module which generates and displays images, and various suitable input devices.

An electronic device including light-emitting elements may include a display module including a display area where light is emitted and a bezel area where light is not emitted, a cover window that protects the display module, and an adhesive film between the display module and the cover window. When penetrative bubbles, which are generated in the process of removing air bubbles generated while bonding the display panel and the window, move beyond the bezel area into the display area, a product may be judged as defective and a yield may be affected (e.g., reduced) by the defect.

### SUMMARY

One or more embodiments of the present disclosure provide a method of minimizing or reducing a bezel area by reducing bubbles in an adhesive layer between a display area and a window of a display apparatus, and provide a display apparatus, an electronic device, and a method of manufacturing the display apparatus in relation to the method of minimizing or reducing the bezel area.

According to one or more embodiments, a display apparatus includes a display module that realizes visible light, a window member opposite to one surface of the display module, and an adhesive layer between the display module and the window member, wherein the adhesive layer is formed by curing an adhesive including at least a high-molecular weight acrylic polymer having a first weight-average molecular weight of at least 700,000 (e.g., 700,000 daltons or more) and a low-molecular weight acrylic polymer having a second weight-average molecular weight of less than 500,000 (e.g., less than 500,000 daltons), the adhesive layer has a stress relaxation value of 0.01 to 0.07 before curing, and a stress relaxation value of 0.30 to 0.50 after curing, and an amount of the high-molecular weight acrylic polymer is at least 30 parts by weight, with respect to 100 parts by weight of a sum of an amount of the high-molecular weight acrylic polymer and an amount of the low-molecular weight acrylic polymer.

In an embodiment, the first weight-average molecular weight may be 700,000 daltons to 3,000,000 daltons.

In an embodiment, the second weight-average molecular weight may be 100,000 daltons to 300,000 daltons.

In an embodiment, the stress relaxation value may be measured at 70° C.

In an embodiment, the adhesive layer may contain a permeable polymer which allows at least some of the visible light to penetrate therethrough.

In an embodiment, the adhesive layer may include a first adhesive layer and a second adhesive layer having different stress relaxation values.

In an embodiment, the second adhesive layer may have a stress relaxation value of 0.4 to 0.6 before and after curing.

In an embodiment, the adhesive layer may further include a third adhesive layer having a smaller stress relaxation value than the second adhesive layer, and the second adhesive layer may be between the first adhesive layer and the third adhesive layer.

In an embodiment, the first adhesive layer and/or the third adhesive layer may have a stress relaxation value of 0.01 to 0.07 before curing, and a stress relaxation value of 0.30 to 0.50 after curing.

In an embodiment, the first adhesive layer may have a creep value of at least 4% at 50° C., a modulus of 0.04 MPa to 0.70 MPa at 25° C., and adhesion of at least 0.5 kgf/in, and the second adhesive layer may have a creep value of at least 4% at 50° C. and a modulus of 0.04 MPa to 0.70 MPa at 25° C.

According to one or more embodiments, a display apparatus includes a display module that realizes visible light, a window member opposite to one surface of the display module, and an adhesive layer between the display module and the window member, wherein the adhesive layer has a stress relaxation value of 0.01 to 0.07 before curing, a stress relaxation value of 0.30 to 0.50 after curing, a creep value of at least 4% at 50° C., and a modulus of 0.04 MPa to 0.70 MPa at 25° C.

In an embodiment, the adhesive layer may be formed by curing an adhesive including at least a high-molecular weight acrylic polymer having a first weight-average molecular weight of at least 700,000 (e.g., 700,000 daltons or more) and a low-molecular weight acrylic polymer having a second weight-average molecular weight of less than 500,000 (e.g., less than 500,000 daltons), and an amount of the high-molecular weight acrylic polymer may be at least 30 parts by weight, with respect to 100 parts by weight of a sum of an amount of the high-molecular weight acrylic polymer and an amount of the low-molecular weight acrylic polymer.

In an embodiment, the first weight-average molecular weight may be 700,000 daltons to 3,000,000 daltons.

In an embodiment, the second weight-average molecular weight may be 100,000 daltons to 300,000 daltons.

In an embodiment, the stress relaxation value may be measured at 70° C.

In an embodiment, the adhesive layer may contain a permeable polymer which allows at least some of the visible light to penetrate therethrough.

In an embodiment, the adhesive layer may include a first adhesive layer and a second adhesive layer having different stress relaxation values.

In an embodiment, the second adhesive layer may have a stress relaxation value of 0.4 to 0.6 before and after curing.

In an embodiment, the adhesive layer may further include a third adhesive layer having a smaller stress relaxation value than the second adhesive layer, and the second adhesive layer may be between the first adhesive layer and the third adhesive layer.

In an embodiment, the first adhesive layer and/or the third adhesive layer may have a stress relaxation value of 0.01 to 0.07 before curing, and a stress relaxation value of 0.30 to 0.50 after curing.

According to one or more embodiments, an electronic device includes a controller configured to generate a scan input signal, a power module configured to generate a scan input voltage, a display module including a display panel divided into a display area in which a pixel circuit is provided and a non-display area around (e.g., surrounding) the display area, the display module that realizes visible light, a window member opposite to one surface of the display module, an adhesive layer between the display module and the window member, and a scan driver provided in the non-display area, and configured to receive the scan input signal and the scan input voltage and output a scan signal to the pixel circuit, wherein the adhesive layer is formed by curing an adhesive including at least a high-molecular weight acrylic polymer having a first weight-average molecular weight of at least 700,000 (e.g., 700,000 daltons or more) and a low-molecular weight acrylic polymer having a second weight-average molecular weight of less than 500,000 (e.g., less than 500,000 daltons), the adhesive layer has a stress relaxation value of 0.01 to 0.07 before curing, and a stress relaxation value of 0.30 to 0.50 after curing, and an amount of the high-molecular weight acrylic polymer is at least 30 parts by weight, with respect to 100 parts by weight of a sum of an amount of the high-molecular weight acrylic polymer and an amount of the low-molecular weight acrylic polymer.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic cross-sectional view of a display apparatus according to an embodiment;

FIG. 2 is a schematic enlarged view of an example of a region A of FIG. 1;

FIG. 3 is a cross-sectional view of a modified example of FIG. 2;

FIG. 4 is a graph of temperature and pressure according to an autoclave process of a display apparatus according to an embodiment;

FIG. 5 is a cross-sectional view showing movement of air in an adhesive layer in section a to b of FIG. 4;

FIG. 6 is a cross-sectional view showing movement of air in the adhesive layer in section b to c of FIG. 4;

FIG. 7 is a graph showing a bubble penetration distance according to a stress relaxation (SR) value of the adhesive layer;

FIG. 8 is a graph showing movement of air inside the adhesive layer according to the SR value of the adhesive layer;

FIG. 9 is a schematic cross-sectional view of an adhesive layer according to an embodiment;

FIG. 10 is a schematic cross-sectional view of an adhesive layer according to another embodiment;

FIG. 11 is a schematic cross-sectional view of an adhesive layer according to still another embodiment;

FIG. 12 is a plan view of a display apparatus according to another embodiment;

FIG. 13 is a schematic cross-sectional view of an area including an edge of FIG. 12;

FIG. 14 is a schematic cross-sectional view of a display apparatus according to still another embodiment; and

FIG. 15 is a block diagram of an electronic device according to embodiments.

### DETAILED DESCRIPTION

As the present disclosure allows for various suitable changes and numerous embodiments, certain embodiments will be illustrated in the drawings and described in more detail in the written description. Effects and features of embodiments of the disclosure and methods of achieving the same will be apparent with reference to embodiments and drawings described below in more detail. The subject matter of the disclosure may, however, be embodied in many different forms and should not be construed as being limited to the embodiments set forth herein.

In the following embodiments, the terms “first,” “second,” and the like are not used in a restrictive sense and are used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

In embodiments disclosed below, when a part, such as a unit, area, or element, is said to be on another part, it will include not only embodiments where the part is directly on the another part, but also embodiments where other intervening units, areas, or elements are present.

In the following embodiments, the terms, such as “connected” or “coupled” do not necessarily mean “two members being directly and/or fixedly connected or coupled,” unless otherwise specified within the context, and do not exclude the intervention of other members between the two members.

Sizes of elements in the drawings may be exaggerated for convenience of explanation. For example, because sizes and thicknesses of elements in the drawings may be arbitrarily illustrated for convenience of explanation, the following embodiments are not limited thereto.

The subject matter of the disclosure will now be described more fully with reference to the accompanying drawings, in which example embodiments of the disclosure are shown. In the description with reference to the drawings, the same or like elements will be given the same reference numeral, and a redundant description thereof may not be repeated.

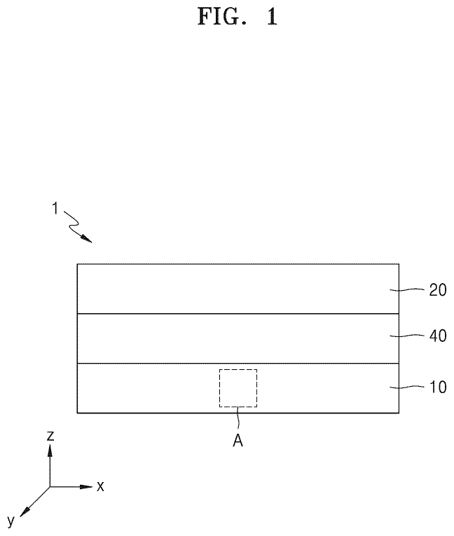

FIG. 1 is a schematic cross-sectional view of a display apparatus according to an embodiment.

Referring to FIG. 1, a display apparatus 1 according to an embodiment may realize light to be emitted in a direction, and for example, upward based on the drawing.

The display apparatus 1 may have various suitable shapes. For example, the display apparatus 1 may have a shape of a flat plate, or as another example, may be a bendable and/or flexible type or kind.

The display apparatus 1 may be one of various suitable types or kinds. For example, the display apparatus may be an organic light-emitting display apparatus, an inorganic light-emitting display apparatus, and/or a quantum dot light-emitting display apparatus. Hereinafter, an organic light-emitting display apparatus will be described as an example. The display apparatus 1 may be implemented as various suitable types or kinds of electronic devices, such as mobile phones, laptop computers, and/or smart watches.

The display apparatus 1 may include a display module 10 which realizes visible light, a window member 20 on a surface of the display module which realizes the visible light, and an adhesive layer 40 between the display module 10 and the window member 20.

The display apparatus 1, for example, may include the display module 10 which realizes the visible light in one direction (in an upward direction of FIG. 1) from an upper surface (for example, an upper surface based on FIG. 1) of the display module 10, the window member 20 which transmits the visible light in one area of the upper surface of the display module 10, and the adhesive layer 40 between the display module 10 and the window member 20.

The adhesive layer 40 which adheres the display module 10 and the window member 20 may include a plurality of layers having different stress relaxation values. Among others, the adhesive layer 40 may include a layer having a stress relaxation value which changes at least before and after curing.

The display apparatus 1 including the adhesive layer 40 may alleviate an introduction of external air into the adhesive layer 40, which may improve (e.g., reduce) a bubble penetration distance and secure a narrow bezel area BZA, may be applied to a curved surface, and may have improved adhesion and ink-step coverage.

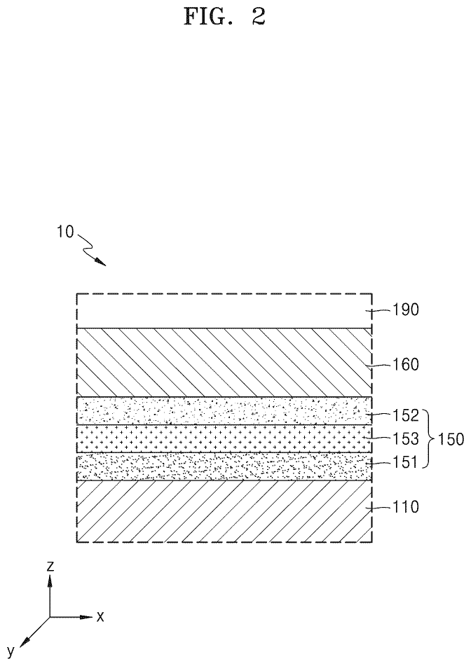

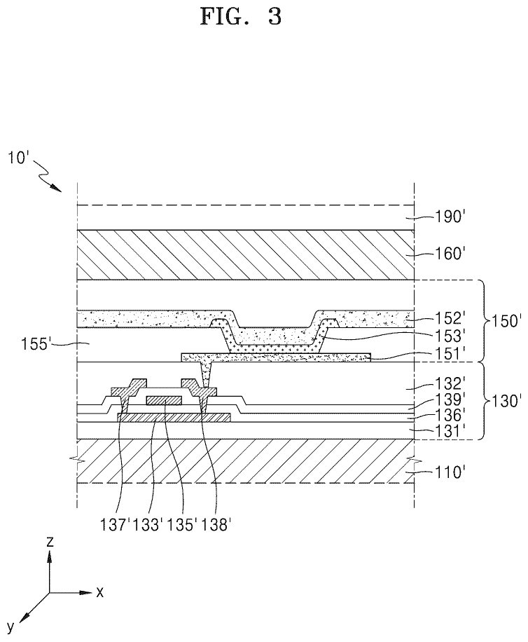

FIG. 2 is a schematic enlarged view of an example of a region A of FIG. 1, and FIG. 3 is a view of a modified example of FIG. 2.

As illustrated in FIG. 2, the display module 10 may include a display element 150 which is capable of realizing visible light to be provided to a user. The display element 150 may be implemented as various suitable types or kinds, and the embodiments disclosed herein describes example embodiments where the display element 150 is an organic light-emitting element.

The display module 10 will be described in more detail. The display module 10 may include a substrate 110, a display element 150, an encapsulation member 160, and an optical functional layer 190.

The substrate 110 may be formed using various suitable materials. For example, the substrate 110 may include a transparent glass material containing SiO₂ as its main component. For example, the substrate 110 may include a transparent plastic (e.g., polymer) material.

The display element 150 may be on the substrate 110 and may include a first electrode 151, a second electrode 152, and an intermediate layer 153. For example, the first electrode 151 may be on the substrate 110, the second electrode 152 may be on the first electrode 151, and the intermediate layer 153 may be between the first electrode 151 and the second electrode 152.

In embodiments, the display apparatus 1 may further include a buffer layer on the first electrode 151 and the substrate 110. The buffer layer may provide a flat surface on the substrate 110 and may block or reduce penetration of moisture and/or gas through the substrate 110.

The first electrode 151 may function as an anode and the second electrode 152 may function as a cathode. In embodiments, the order of these polarities may be reversed. In embodiments where the first electrode 151 functions as an anode, the first electrode 151 may contain ITO, IZO, ZnO, In₂O₃, and/or the like, which has a high work function. For example, depending on the purpose and design conditions, the first electrode 151 may further include a reflection film, which may include Ag, Mg, Al, Pt, Pd, Au, Ni, Nd, Ir, Cr, Li, Yb, and/or Ca.

In embodiments where the second electrode 152 functions as a cathode, the second electrode 152 may include a metal, such as Ag, Mg, Al, Pt, Pd, Au, Ni, Nd, Ir, Cr, Li, and/or Ca. In some embodiments, the second electrode 152 may contain ITO, IZO, ZnO, and/or In₂O₃ to enable light transmission.

The intermediate layer 153 may have at least an organic light-emitting layer. In some embodiments, the intermediate layer 153 may optionally include at least one of a hole injection layer, a hole transport layer, an electron transport layer, or an electron injection layer, in addition to the organic light-emitting layer. In embodiments where a voltage is applied to the first electrode 151 and the second electrode 152, visible light may be generated from the intermediate layer 153, for example, from the organic light-emitting layer of the intermediate layer 153.

The encapsulation member 160 may be on the display element 150 to protect the display element 150. The encapsulation member 160 may protect the display element 150 from external impacts and reduce or suppress the penetration of external foreign substances, moisture, and/or the like.

The encapsulation member 160 may be formed in various suitable types or kinds. As an optional embodiment, the encapsulation member 160 may include a transparent glass material containing SiO₂ as a main component. As another optional embodiment, the encapsulation member 160 may include a plastic (e.g., polymer) material which is light-transmittable. As still another optional embodiment, the encapsulation member 160 may be formed by using an inorganic film and/or an organic film. As still another optional embodiment, the encapsulation member 160 may be formed by stacking one or more organic layers and one or more inorganic layers. In this embodiment, optionally, the organic layers and the inorganic layers may be stacked in an alternating manner.

As an optional embodiment, the display module 10 may further include the optical functional layer 190. The optical functional layer 190 may include a layer to improve, change, and perform other various suitable controls of characteristics of light realized in the display element 150.

As an optional embodiment, the display module 10 may include a thin film transistor which transmits a signal, which is utilized or required for operation of the display element 150, to the display element 150. This will be explained in more detail with reference to FIG. 3.

FIG. 3 is a view of a modified example of FIG. 2; Referring to FIG. 3, a display module 10′ may include a substrate 110′, a display element 150′, a thin film transistor 130′, an encapsulation member 160′, and an optical functional layer 190′.

The thin film transistor 130′ may include an active layer 133′, a gate electrode 135′, a source electrode 137′, and a drain electrode 138′. This will be explained in more detail. A buffer layer 131′ may be on the substrate 110′. The buffer layer 131′ may suppress or reduce penetration of impurity elements through the substrate 110′ and provide a flat surface on top of the substrate 110′, and may include various suitable materials capable of playing such roles. The buffer layer 131′ may also be omitted because it is an optional component.

The active layer 133′ may be provided as a set or certain pattern on the buffer layer 131′. The active layer 133′ may include an inorganic semiconductor material, such as silicon, may include an organic semiconductor material as an optional embodiment, and/or may contain an oxide semiconductor material as another optional embodiment.

A gate insulating layer 136′ may be on the active layer 133′. The gate insulating layer 136′ may include various suitable insulating materials (e.g., electrically insulating materials), and may be formed using, for example, an oxide and/or a nitride.

The gate electrode 135′ may be on the gate insulating layer 136′ to correspond to a set or certain region of the active layer 133′. The gate electrode 135′ may include a material having high conductivity (e.g., high electrical conductivity). For example, the gate electrode 135′ may contain Au, Ag, Cu, Ni, Pt, Pd, Al, or Mo, and may contain an alloy, such as Al:Nd, Mo:W, and/or the like. However, this merely an example. The present disclosure is not limited thereto and the gate electrode 135′ may include various suitable materials.

An interlayer insulating layer 139′ (e.g., an interlayer electrically insulating layer) may cover the gate electrode 135′. The source electrode 137′ and the drain electrode 138′ may be on the interlayer insulating layer 139′. The source electrode 137′ and the drain electrode 138′ may be in contact with a set or certain region of the active layer 133′.

A passivation layer 132′ may cover the source electrode 137′ and the drain electrode 138′. In embodiments, a separate insulating layer (e.g., electrically insulating layer) may further be on the passivation layer 132′ to planarize the thin film transistor 130′.

The display module 10′ may further include one or more thin film transistors 130′ that are electrically connectible to the display element 150′, and in embodiments, may further include one or more capacitors that are electrically connectible to the display element 150′ or the thin film transistors 130′.

A first electrode 151′ may be on the passivation layer 132′. The first electrode 151′ may be electrically connected to one of the source electrode 137′ or the drain electrode 138′. For example, the first electrode 151′ may be connected to the drain electrode 138′.

A pixel defining layer 155′ may be on the first electrode 151′ and may expose a set or certain area of the first electrode 151′.

An intermediate layer 153′ may be on the first electrode 151′. The intermediate layer 153′ may include an organic light-emitting layer. As an optional embodiment, the intermediate layer 153′ may further include at least one of a hole injection layer, a hole transport layer, an electron transport layer, or an electron injection layer, in addition to the organic light-emitting layer.

A second electrode 152′ may be on the intermediate layer 153′.

The encapsulation member 160′ may be on the display element 150′ to protect the display element 150′.

As an optional embodiment, the display module 10′ may further include the optical functional layer 190′. The optical functional layer 190′ may further include a layer to improve, change, and perform other various suitable controls of characteristics of light which is realized in the display element 150′.

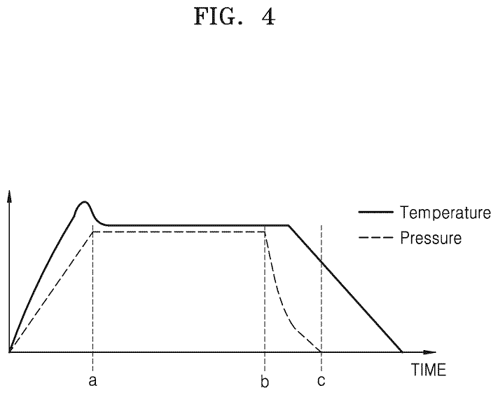

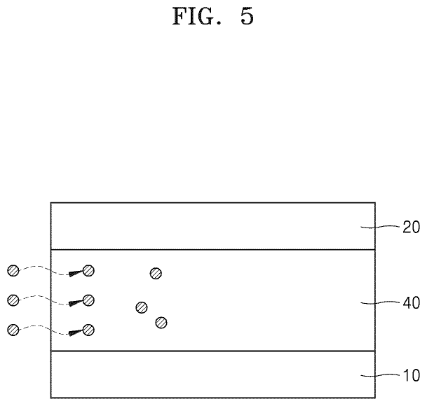

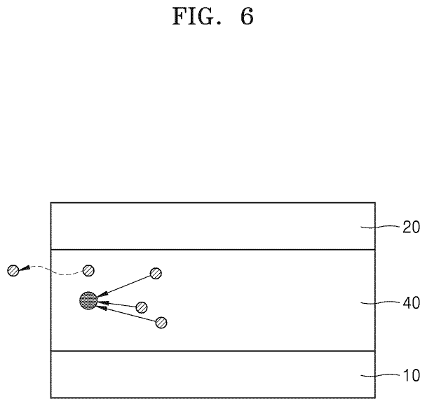

FIG. 4 is a graph of temperature and pressure according to an autoclave process of a display apparatus according to an embodiment, FIG. 5 is a view showing movement of air in an adhesive layer in section a to b of FIG. 4, and FIG. 6 is a view showing movement of air in the adhesive layer in section b to c of FIG. 4.

The display apparatus 1 may include a display area DA where an image is displayed and a bezel area BZA where an image is not displayed. Technologies have advanced in a direction of reducing the bezel area BZA of the display apparatus. Penetrative bubbles may be generated as a side effect of a process of removing air bubbles generated after bonding the display module 10 and the window member 20. Products with bubbles present in the display area DA are defective. A bubble penetration distance may be reduced by improving material properties of the adhesive layer 40 because the bubble penetration distance of the adhesive layer 40 involves a length of the bezel area BZA.

An autoclave process may be performed to remove bonding bubbles generated after the process of bonding the display module 10 and the window member 20. The autoclave process may improve the effect of removing bonding bubbles as a process time extends under high-temperature and high-pressure conditions. In some embodiments, as the autoclave process is carried out for a longer time under the high-temperature and high-pressure conditions, more penetrative bubbles may be generated due to an introduction of external air as a side effect. The display apparatus 1 may be considered good when the penetrative bubbles penetrate the bezel area BZA, but may be considered as defective when the penetrative bubbles penetrate the display area DA.

A mechanism of the autoclave process according to temperature and pressure will be described with reference to FIG. 4. Under high-temperature and high-pressure conditions, the adhesive layer 40 may be softened and the bonding bubbles may be better discharged to the outside of the adhesive layer 40. For example, in a time interval from 0 to a, temperature and pressure may increase to create good conditions to remove penetrative bubbles. In section a to b, the high-temperature and high-pressure conditions may be maintained so that bonding bubbles are discharged to the outside. In section b to c, the autoclave process may be completed by lowering the pressure and temperature.

FIG. 5 illustrates the flow of bubbles in the adhesive layer 40 in the time interval from a to b of FIG. 4, which corresponds to a holding time interval (or holding time) of the autoclave process. In the time interval from a to b, the bonding bubbles inside the adhesive layer 40 may be removed, but as a side effect of the autoclave process, external air may penetrate the adhesive layer 40.

The holding time interval (e.g., the time interval from a to b) may be maintained (carried out) at relatively high temperature to increase ductility of the adhesive layer 40, so that the bonding bubbles may be discharged well from the adhesive layer 40. For example, the holding time interval may be maintained (carried out) under high-pressure conditions, so that the bonding bubbles are discharged to the outside of the adhesive layer 40. However, under conditions exceeding set or certain temperature and pressure, external air may also easily penetrate the softened adhesive layer 40 as a side effect. During the holding time interval, a temperature and pressure may be set so that the bonding bubbles are well discharged from the adhesive layer 40 and external air is not easily introduced. As an example, the holding time interval (e.g., the time interval from a to b) of the autoclave process may be maintained at a pressure of 5 bar and a temperature of 50° C.

FIG. 6 illustrates the flow of bubbles in the adhesive layer 40 in the time interval from b to c of FIG. 4, which corresponds to a discharge time interval of the autoclave process. In the time interval from b to c, both the bonding bubbles inside the adhesive layer 40 and the bubbles that have penetrated the adhesive layer 40 during the holding time interval may be discharged.

The discharge time interval may be a final section of the autoclave process, and the temperature and pressure may decrease again in the discharge time interval. In the time interval from b to c, which is the discharge time interval, the temperature may fall at a constant (e.g., a substantially constant) level, as in the time interval from 0 to a, but the pressure may fall rapidly due to rapid air exhaust. The rapid pressure fall may cause the penetrative bubbles inside the adhesive layer 40 to be trapped inside the adhesive layer 40 without being discharged externally.

The display apparatus 1 in which the bubbles trapped inside the adhesive layer 40 are located in the display area DA may be defective. Therefore, a description will be given herein of the adhesive layer 40 which has an improved bubble penetration distance to secure a narrow bezel area BZA and has enhanced adhesion between the display module 10 and the window member 20.

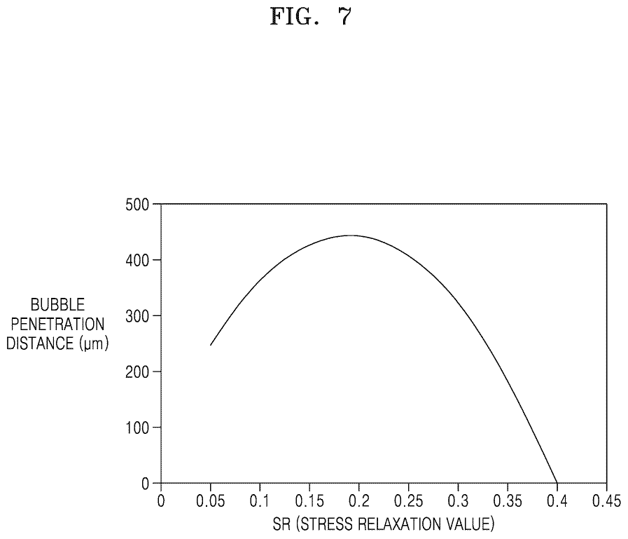

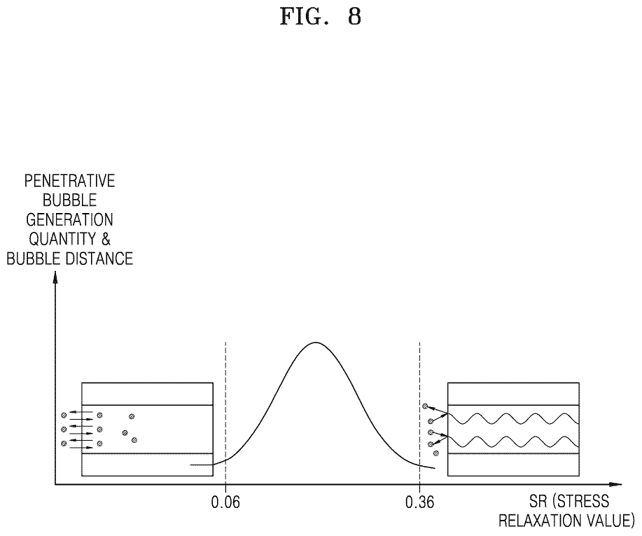

FIG. 7 is a graph showing a bubble penetration distance according to a stress relaxation value of the adhesive layer, and FIG. 8 is a graph showing movement of air inside the adhesive layer according to the stress relaxation value of the adhesive layer.

Referring to FIG. 7, a penetrative bubble generation distance and the number of penetrative bubbles may be correlated with a stress relaxation value. A penetrative bubble generation distance may tend to decrease when a stress relaxation value is less than about 0.2, and the penetrative bubbles may not be generated when the stress relaxation value is at least about 0.4.

Stress relaxation may refer to a reduction in internal stress of a viscous and elastic object over time while the object maintains a constant (e.g., substantially constant) stain.

A stress relaxation value denotes a degree to which an object recovers to its original state after being relaxed or compressed, and hereinafter, may be defined as a value obtained by dividing a stress value at 300 seconds after strain by a stress value at 0.01 second after strain while maintaining strain of 25%. For example, a stress relaxation value may be a value obtained by dividing a stress value when strain of 25% is applied for 300 seconds by a stress value when the strain of 25% is applied for 0.01 second. According to an embodiment, stress values may each be measured at 70° C. For example, the stress relaxation values may be measured at approximately 70° C.

An object may be close to a liquid and may not easily recover in case that a stress relaxation value is close to 0, and may be close to a solid and may easily recover in case that the stress relaxation value is close to 1.

Crosslink density refers to the ratio of crosslinked structural units in a crosslinked polymer to the total structural units, and the stress relaxation value may be a measure of the crosslink density of the polymer. The stress relaxation value and the crosslink density value may be proportional to each other, such that the crosslink density value increases as the stress relaxation value increases while decreasing as the stress relaxation value decreases.

When the adhesive layer 40 has a too small (low) stress relaxation value, the adhesive layer 40 may have a small (low) crosslink density value and adhesion between the display module 10 and the window member 20 may decrease accordingly. This may cause the window member 20 to come off the display module 10, and deteriorate reliability of the display apparatus 1.

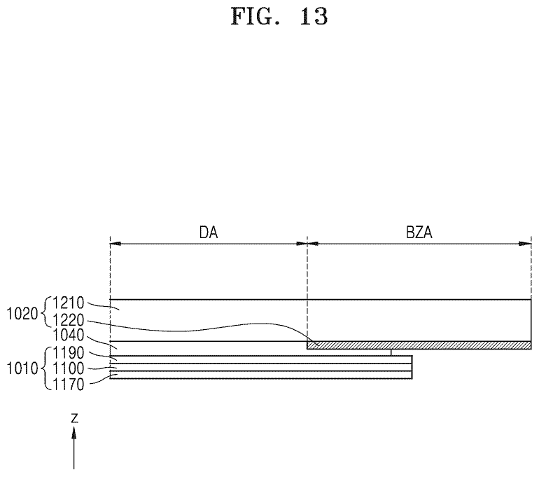

The adhesive layer 40 may have a great (high) crosslink density value when the adhesive layer 40 has an excessively great (high) stress relaxation value. This may suppress or reduce penetration of external air and remove bonding bubbles. However, an ink-step coverage and adhesion may deteriorate and the display module 10 may be difficult to be applied to a curved surface because the adhesive layer 40 is hard. In some embodiments, an ink-step coverage and adhesion of a light-shielding member 1220 (see FIG. 13) on the window member 20 may deteriorate, causing a trouble in applying the display module 10 to a curved surface.

The adhesive layer 40 may be selected as a material, which may allow the display module 10 to have a curved surface, have high adhesion, and have a stress relaxation value suitable to remove bonding bubbles while reducing the penetration of external air.

The adhesive layer 40 may contain a permeable polymer, which permeates at least some of visible light, and as an example, may include a transparent acrylic polymer. In other embodiments, the adhesive layer 40 may be an optically clear adhesive (OCA) layer and/or a pressure sensitive adhesive (PSA) layer in which a low-molecular weight polymer and a high-molecular weight polymer are mixed.

The adhesive layer 40 referred to as OCA may be manufactured by curing a monomer solution using ultraviolet rays (hereinafter, referred to as UV-curing) and coating the cured resultant. The OCA may be classified into a UV-curable OCA, a UV-non-curable OCA, or the like.

For example, a UV-curable OCA may be manufactured as the adhesive layer 40 by primarily UV-curing a monomer solution, bonding (performing a lamination process of) the display module 10, the primarily UV-cured film, and the window member 20, and then secondarily UV-curing the primarily UV-cured film. The primarily UV-cured film may have a small stress relaxation value, which may exhibit excellent ink-step coverage and adhesion. Due to this, even when the primarily UV-cured film has a high stress relaxation value and thus has a hard characteristic due to the secondary UV-curing, the UV-curable OCA may have a relatively small thickness, which may reduce the weight of the display apparatus 1.

At least 30% of the mass of the adhesive layer 40 may be a polymer having a molecular weight of at least 700,000 (e.g., at least 700,000 daltons). In some embodiments, the adhesive layer 40 may be formed by primarily curing a composition including a high-molecular weight acrylic polymer having a first weight-average molecular weight of at least 700,000 (e.g., at least 700,000 daltons), a low-molecular weight acrylic polymer having a second weight-average molecular weight of less than 500,000 (e.g., less than 500,000 daltons), a crosslinker, a photoinitiator, a molecular weight regulator, or any combination thereof. The amount of the high-molecular weight acrylic polymer may be at least 30 parts by weight with respect to 100 parts by weight, which is the sum of the amount of the high-molecular weight acrylic polymer and the amount of the low-molecular weight acrylic polymer.

The adhesive layer 40 may have a creep of at least about 4% at about 50° C. and a modulus of about 0.04 MPa to about 0.70 MPa at 25° C.

According to an embodiment, the creep of the adhesive layer 40 at about 50° C. may be about 4% to about 100%, about 5% to about 90%, about 6% to about 80%, about 7% to about 70%, about 8% to about 60%, about 9% to about 50%, about 10% to about 40%, about 5% to about 20%, about 5% to about 19%, about 5% to about 18%, about 5% to about 17%, about 5% to about 16%, about 5% to about 15%, about 5% to about 14%, about 5% to about 13%, about 5% to about 12%, about 5% to about 11%, or about 5% to about 10%, about 6% to about 14%, about 7% to about 13%, about 8% to about 12%, or about 9% to about 11%.

According to an embodiment, the modulus of the adhesive layer 40 may be about 0.04 MPa to about 0.70 MPa, about 0.08 MPa to about 0.60 MPa, about 0.12 MPa to about 0.50 MPa, about 0.15 MPa to about 0.40 MPa, about 0.18 MPa to about 0.30 MPa, or about 0.20 MPa.

The modulus may be expressed as a modulus value at room temperature (25° C.), which is an actual usage temperature, after measuring the modulus for each temperature using a rheometer.

According to an embodiment, the adhesion of the adhesive layer 40 may be approximately at least 300 gf/28 mm. The adhesion may be an average value calculated by measuring the adhesion of the adhesive layer 40 plural times. For example, the adhesion of the adhesive layer 40 may be at least about 310 gf/28 mm, at least about 320 gf/28 mm, about 300 gf/28 mm to about 500 gf/28 mm, about 310 gf/28 mm to about 400 gf/28 mm, or about 320 gf/28 mm to about 390 gf/28 mm.

An adhesive forming the adhesive layer 40 may include at least the following: an oligomer, a monomer, a photoinitiator, a crosslinker, and/or a molecular weight regulator. The monomer may be an acrylic monomer and may contain, for example, at least ethylhexyl acrylate (EHA), hydroxyethyl acrylate (HEA), or isobornyl acrylate (IBOA). As an example, the adhesive layer 40 may contain a photoinitiator to have the properties of a UV-curable OCA.

An example of the adhesive may include 2-ethylhexyl acrylate (2-EHA) as an oligomer, which may be in an amount of 75% to 85% of the amount of the adhesive. The monomer may include 2-hydroxyethyl acrylate (2-HEA) and may be in an amount of 15% to 25% of the amount of the adhesive. The photoinitiator may include Irgacure 184 and may be in an amount of 0.1% to 0.4% of the amount of the adhesive. The crosslinker may include 1,6-hexanediol diacrylate (HDDA) and/or polyethylene glycol diacrylate (PEGDA), and may be in an amount of 0.1% to 0.5% of the amount of the adhesive. The molecular weight modifier may include n-dodecyl mercaptan and may be in an amount of 0.1% to 0.2% of the amount of the adhesive.

The photoinitiator of the adhesive may form radicals by UV, and the radicals may attack double bonds of the monomer, causing a polymer chain to grow through a chain reaction, thereby forming the adhesive layer 40.

An example of the adhesive may be applied to the display module 10 by a coating facility and then UV-cured into a film type or kind, thereby forming the adhesive layer 40. As another example, a step of preparing an adhesive formed in a film type or kind may be performed, and the film-type adhesive may be used in a process of manufacturing a display apparatus. First, as the step of preparing the adhesive formed in the film type, an adhesive may be formed into a film type or kind by UV-curing, and then release films may be attached to respective surfaces of the film. In the subsequent manufacturing process of the display apparatus, the release film on one surface of the film-type adhesive may be removed such that the corresponding surface adheres to the window member 20, and the release film on the other surface of the film-type adhesive may be removed such that the other surface adheres to the display module 10, thereby forming the adhesive layer 40.

Thereafter, an autoclave process and an aging process may be performed on the adhesive layer 40 to remove air bubbles bonded to the adhesive layer 40.

In some embodiments, referring to FIG. 8, it may be seen that a generation amount of bubbles, which penetrate the adhesive layer 40, and a bubble penetration distance increase when a stress relaxation value is in a range of 0.06 to 0.36.

In a time interval where the stress relaxation value of the adhesive layer 40 is less than 0.06, bubbles may smoothly move in and out of the adhesive layer 40 because of the low stress relaxation value, thereby reducing the bubble penetration distance and improving the ink-step coverage.

In a time interval where the stress relaxation value of the adhesive layer 40 is in the range of 0.06 to 0.36, crosslinking of polymers of the adhesive layer 40 may take place. When a set or certain stress relaxation value is exceeded, the movement of bubbles may be restricted and thereby the bubbles may not be smoothly discharged from the adhesive layer 40, causing generation of penetrative bubbles.

When a time interval where the stress relaxation value of the adhesive layer 40 exceeds 0.36, a strong network may be formed among the polymers of the adhesive layer 40, which may suppress or reduce air penetration into the adhesive layer 40, thereby reducing the chance of generation of the penetrative bubbles.

According to an embodiment, the single-layer adhesive layer 40 may have a stress relaxation value of 0.01 to 0.07 before curing, may have a stress relaxation value of 0.30 to 0.50 after curing, and may be formed by curing an adhesive, which includes at least a high-molecular weight acrylic polymer having a first weight-average molecular weight of at least 700,000 (e.g., 700,00 or more), a low-molecular weight acrylic polymer having a second weight-average molecular weight of less than 500,000 (e.g., less than 500,000 daltons), a crosslinker, a photoinitiator, a molecular weight regulator, or any combination thereof. The amount of the high-molecular weight acrylic polymer may be at least 30 parts by weight with respect to 100 parts by weight, which is the sum of the amount of the high-molecular weight acrylic polymer and the amount of the low-molecular weight acrylic polymer. The adhesive layer 40 may be a UV-curable OCA, and the weight-average molecular weight may be measured using a gel permeation chromatography (GPC) method.

According to an embodiment of the single-layer adhesive layer 40, with respect to 100 parts by weight, which is the sum of the amount of the high-molecular weight acrylic polymer and the amount of the low-molecular weight acrylic polymer, the amount of the high-molecular weight acrylic polymer may be about 30 parts by weight to about 99 parts by weight, about 30 parts by weight to about 95 parts by weight, about 30 parts by weight to about 90 parts by weight, about 30 parts by weight to about 85 parts by weight, about 30 parts by weight to about 80 parts by weight, about 30 parts by weight to about 75 parts by weight, about 30 parts by weight to about 70 parts by weight, about 30 parts by weight to about 65 parts by weight, about 30 parts by weight to about 60 parts by weight, about 30 parts by weight to about 55 parts by weight, about 30 parts by weight to about 50 parts by weight, about 30 parts by weight to about 45 parts by weight, about 30 parts by weight to about 40 parts by weight, or about 30 parts by weight to 35 parts by weight.

According to an embodiment of the single-layer adhesive layer 40, the stress relaxation value of the adhesive layer 40 before curing may be about 0.01 to about 0.40, about 0.01 to about 0.30, about 0.01 to about 0.20, about 0.01 to about 0.12, about 0.01 to about 0.11, about 0.01 to about 0.10, about 0.01 to about 0.09, about 0.01 to about 0.08, about 0.01 to about 0.05, about 0.02 to about 0.40, about 0.02 to about 0.30, about 0.02 to about 0.20, about 0.02 to about 0.12, about 0.02 to about 0.11, about 0.02 to about 0.10, about 0.02 to about 0.09, about 0.02 to about 0.08, about 0.02 to about 0.05, about 0.03 to about 0.40, about 0.03 to about 0.30, about 0.03 to about 0.20, about 0.03 to about 0.15, about 0.03 to about 0.12, about 0.03 to about 0.11, about 0.03 to about 0.10, about 0.03 to about 0.09, about 0.03 to about 0.08, or about 0.03 to about 0.05.

According to an embodiment of the single-layer adhesive layer 40, the stress relaxation value of the adhesive layer 40 after curing may be about 0.20 to about 0.70, and may be, for example, about 0.20 to about 0.65, about 0.20 to about 0.60, about 0.20 to about 0.55, about 0.20 to about 0.50, about 0.20 to about 0.45, about 0.20 to about 0.40, about 0.20 to about 0.35, about 0.20 to about 0.30, about 0.20 to about 0.25, about 0.25 to about 0.65, about 0.25 to about 0.60, about 0.25 to about 0.55, about 0.25 to about 0.50, about 0.25 to about 0.45, about 0.25 to about 0.40, about 0.25 to about 0.35, or about 0.25 to about 0.30. Curing may be carried out by irradiating the adhesive layer 40 with ultraviolet light in a quantity of about 500 mJ to about 1500 mJ.

According to an embodiment of the single-layer adhesive layer 40, the stress relaxation value of the cured adhesive layer 40 may be greater than the stress relaxation value of the adhesive layer 40 before curing. The variation of the stress relaxation value may range from about 50% to about 600%, for example, about 70% to about 560%.

According to an embodiment of the single-layer adhesive layer 40, the first weight-average molecular weight may be about 700,000 daltons to about 3,000,000 daltons. For example, the first weight-average molecular weight may be about 700,000 daltons to about 1,500,000 daltons or about 700,000 daltons to about 1,000,000 daltons.

According to an embodiment of the single-layer adhesive layer 40, the second weight-average molecular weight may be about 50,000 daltons to about 490,000 daltons. For example, the second weight-average molecular weight may be about 70,000 daltons to about 400,000 daltons or about 100,000 daltons to about 300,000 daltons.

According to an embodiment of the single-layer adhesive layer 40, each of the high-molecular weight acrylic polymer and the low-molecular weight acrylic polymer may be a polymer of a first compound of 2-ethylhexyl acrylate and a second compound of 2-hydroxyethyl acrylate.

According to an embodiment of the single-layer adhesive layer 40, when the high-molecular weight acrylic polymer is a polymer of the first compound and the second compound, the amount of the first compound may be about 75 parts by weight to about 85 parts by weight and the amount of the second compound may be about 15 parts by weight to about 25 parts by weight, with respect to a total of 100 parts by weight of the high-molecular weight acrylic polymer.

According to another embodiment of the single-layer adhesive layer 40, in case that the low-molecular weight acrylic polymer is a polymer of the first compound and the second compound, the amount of the first compound may be about 75 parts by weight to about 85 parts by weight and the amount of the second compound may be about 15 parts by weight to about 25 parts by weight, with respect to a total of 100 parts by weight of the low-molecular weight acrylic polymer.

The crosslinker included in the single-layer adhesive layer 40 may be 1,6-hexanediol diacrylate and/or poly(ethylene glycol) diacrylate. According to an embodiment, the single-layer adhesive layer 40 may further include the crosslinker, and the amount of the crosslinker may be about 0.01 part by weight to about 0.5 part by weight, with respect to 100 parts by weight of the sum of the amount of the high-molecular weight acrylic polymer and the amount of the low-molecular weight acrylic polymer.

The photoinitiator included in the single-layer adhesive layer 40 may be (1-hydroxycyclohexyl)(phenyl)methanone. According to an embodiment, the single-layer adhesive layer 40 may further include the photoinitiator, and the amount of the photoinitiator may be about 0.01 part by weight to about 0.4 part by weight, with respect to 100 parts by weight as the sum of the amount of the high-molecular weight acrylic polymer and the amount of the low-molecular weight acrylic polymer.

The molecular weight regulator included in the single-layer adhesive layer 40 may be n-dodecyl mercaptan. According to an embodiment, the single-layer adhesive layer 40 may further include the molecular weight regulator, and the amount of the molecular weight regulator may be about 0.01 part by weight to about 0.2 part by weight, with respect to 100 parts by weight as the sum of the amount of the high-molecular weight acrylic polymer and the amount of the low-molecular weight acrylic polymer.

Unlike the single-layer adhesive layer 40, as another example that has both the advantage in the section where the stress relaxation value of the adhesive layer 40 is 0.06 or less and the advantage in the section where the stress relaxation value is at least 0.36, an adhesive layer having different stress relaxation values before and after curing, namely, a plurality of adhesive layers having different stress relaxation values may be introduced.

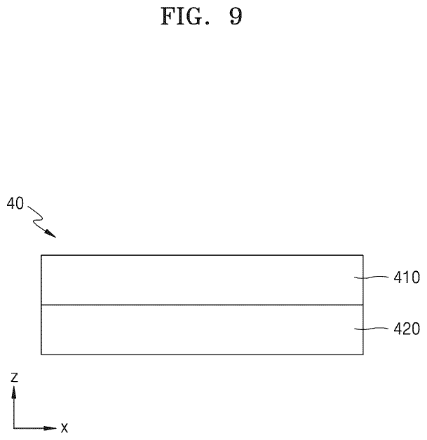

FIG. 9 is a schematic cross-sectional view of an adhesive layer according to an embodiment.

The adhesive layer 40 may include a first adhesive layer 410 and a second adhesive layer 420. The first adhesive layer 410 may be on the second adhesive layer 420. The first adhesive layer 410 may be on the second adhesive layer 420 based on a Z-axis.

The first adhesive layer 410 may have a smaller stress relaxation value than the second adhesive layer 420. The first adhesive layer 410 may have a stress relaxation value of 0.01 to 0.07 before curing, and may have a stress relaxation value of 0.30 to 0.50 after curing.

The first adhesive layer 410 may be in contact with the window member 20. The first adhesive layer 410 before curing may have a relatively low stress relaxation value of 0.01 to 0.07 to adhere well to the window member 20, and have a suitably or sufficiently low crosslink density value to reduce penetrative bubbles, such that smooth inflow and outflow of air may be allowed. In embodiments, the first adhesive layer 410 having the relatively low stress relaxation value before curing may exhibit a good ink-step coverage and enable application of a curved structure.

The first adhesive layer 410 may be cured after being bonded to the window member 20, to adhere well to the window member 20. This may increase the stress relaxation value of the first adhesive layer 410 and alleviate the generation of the penetrative bubbles.

The first adhesive layer 410 after curing may have a relatively high stress relaxation value of 0.30 to 0.50, and have a crosslink density value which is suitably or sufficiently high to reduce the penetrative bubbles, thereby suppressing or reducing air penetration.

The second adhesive layer 420 may have a stress relaxation value of 0.4 to 0.6 before and after curing. The second adhesive layer 420 may have a stress relaxation value, which is higher than those of the first adhesive layer 410 before and after curing and is suitably or sufficiently high to reduce the penetrative bubbles. Accordingly, the second adhesive layer 420 may block or reduce the introduction of external air and alleviate the permeation of bubbles.

The first adhesive layer 410 and the second adhesive layer 420 may each adopt the adhesive layer 40 described with reference to FIGS. 7 and 8, as long as not conflicted with the above description.

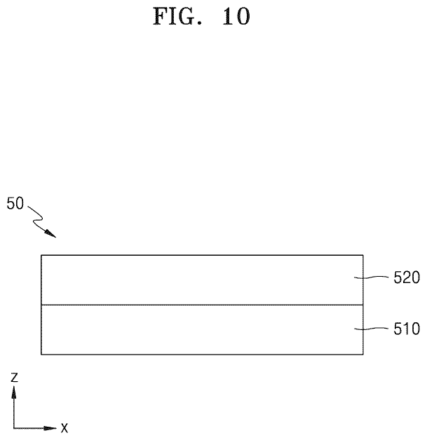

FIG. 10 is a schematic cross-sectional view of an adhesive layer according to another embodiment.

An adhesive layer 50 may include a first adhesive layer 510 and a second adhesive layer 520 on the first adhesive layer 510. The second adhesive layer 520 may be on the first adhesive layer 510 based on a Z-axis.

The first adhesive layer 510 may have a smaller stress relaxation value than the second adhesive layer 520. The first adhesive layer 510 may have a stress relaxation value of 0.01 to 0.07 before curing, and a stress relaxation value of 0.30 to 0.50 after curing.

The first adhesive layer 510 may be in contact with the display module 10. The first adhesive layer 510 before curing may have a relatively low stress relaxation value of 0.01 to 0.07 to adhere well to the display module 10, and have a crosslink density value, which is suitably or sufficiently low to reduce penetrative bubbles, such that smooth inflow and outflow of air may be allowed. In embodiments, the first adhesive layer 510 having the relatively low stress relaxation value before curing may exhibit a good ink-step coverage and enable application of a curved structure.

The first adhesive layer 510 may be cured after being bonded to the display module 10, to adhere well to the display module 10. This may increase the stress relaxation value of the first adhesive layer 410 and alleviate the generation of the penetrative bubbles.

The first adhesive layer 510 after curing may have a relatively high stress relaxation value of 0.30 to 0.50, and have a crosslink density value, which is suitably or sufficiently high to reduce the penetrative bubbles, thereby suppressing or reducing air penetration.

The second adhesive layer 520 may have a stress relaxation value of 0.4 to 0.6 before and after curing. The second adhesive layer 520 may have a stress relaxation value, which is higher than those of the first adhesive layer 510 before and after curing and is suitably or sufficiently high to reduce the penetrative bubbles. Accordingly, the second adhesive layer 520 may block or reduce the introduction of external air and alleviate the permeation of bubbles.

The first adhesive layer 510 and the second adhesive layer 520 may each adopt the adhesive layer 40 described with reference to FIGS. 7 and 8, as long as not conflicted with the above description.

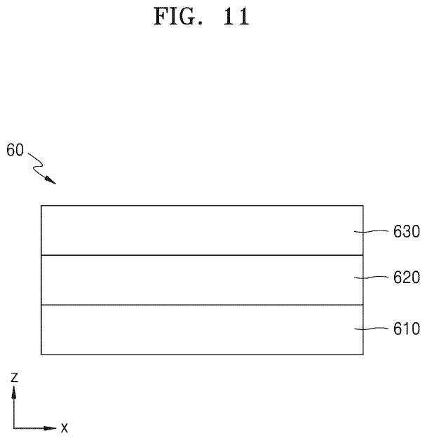

FIG. 11 is a schematic cross-sectional view of an adhesive layer according to still another embodiment.

An adhesive layer 60 may include a first adhesive layer 610, a second adhesive layer 620 on the first adhesive layer 610, and a third adhesive layer 630 on the second adhesive layer 620. The second adhesive layer 620 may be on the first adhesive layer 610 and the third adhesive layer 630 may be on the second adhesive layer 620, on the basis of the Z-axis.

The first adhesive layer 610 and the third adhesive layer 630 may have smaller stress relaxation values than the second adhesive layer 620. The first adhesive layer 610 and the third adhesive layer 630 may have stress relaxation values of 0.01 to 0.07 before curing, and stress relaxation values of 0.30 to 0.50 after curing. In an optional embodiment, the first adhesive layer 610 and the third adhesive layer 630 may have the same stress relaxation value.

The first adhesive layer 610 may be in contact with the display module 10, and the third adhesive layer 630 may be in contact with the window member 20. The first adhesive layer 610 and the third adhesive layer 630 may have a relatively low stress relaxation value of 0.01 to 0.07 before curing, so that the first adhesive layer 610 adheres well to the display module 10 and the third adhesive layer 630 adheres well to the window member 20, and may have a crosslinking density value, which is suitably or sufficiently low to reduce penetrative bubbles, such that smooth inflow or outflow of air may be allowed. In some embodiments, the first adhesive layer 610 and the third adhesive layer 630 having the relatively low stress relaxation value before curing may exhibit a good ink-step coverage and enable application of a curved structure.

The adhesive layer 60 may be cured after being bonded to the display module 10, such that the first adhesive layer 610 adheres well to the display module 10 and the third adhesive layer 630 adheres well to the window member 20. This may increase the stress relaxation value of the adhesive layer 60 and alleviate the generation of the penetrative bubbles.

The first adhesive layer 610 and the third adhesive layer 630 after curing may have a relatively high stress relaxation value of 0.30 to 0.50, and have a crosslink density value, which is suitably or sufficiently high to reduce the penetrative bubbles, thereby suppressing or reducing air penetration.

The second adhesive layer 620 may be between the first adhesive layer 610 and the third adhesive layer 630. The second adhesive layer 620 may have a stress relaxation value of 0.4 to 0.6 before and after curing and the stress relaxation value may be suitably or sufficiently high to reduce the penetrative bubbles. Accordingly, the second adhesive layer 620 may block or reduce the introduction of external air and alleviate the penetration of bubbles.

In embodiments, the second adhesive layer 620 may be between the first adhesive layer 610 and the third adhesive layer 630, which have the lower stress relaxation value than the second adhesive layer 620. Accordingly, the second adhesive layer 620 having relatively low adhesion due to the relatively high stress relaxation value may be supplemented by the first adhesive layer 610 and the third adhesive layer 630 as outer layers having relatively high adhesion. The structural stability of the display apparatus 1 may be improved by sequentially stacking the second adhesive layer 620 on the first adhesive layer 610 and the third adhesive layer 630 on the second adhesive layer 620.

The first adhesive layer 610, the second adhesive layer 620, and the third adhesive layer 630 may each adopt the adhesive layer 40 described with reference to FIGS. 7 and 8, as long as not conflicted with the above description.

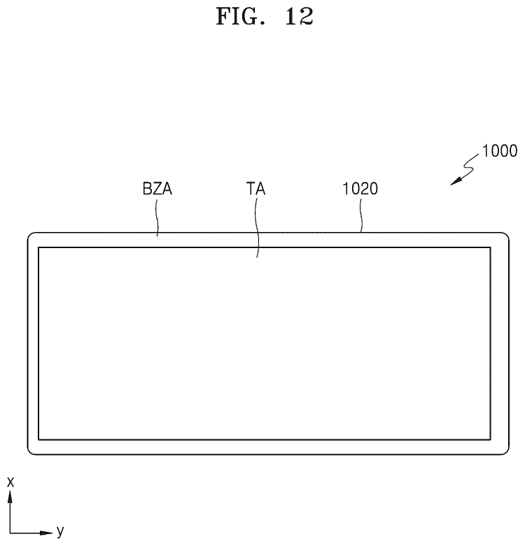

FIG. 12 is a plan view of a display apparatus according to another embodiment, and FIG. 13 is a schematic cross-sectional view of an area including an edge of FIG. 12.

Referring to FIG. 12, the display apparatus 1000 may display an image to be parallel to each of X-axis and Y-axis and toward a Z-axis. A display area DA where an image is displayed may correspond to a front surface of the display apparatus 1000. The image may include a still image as well as a moving image.

In an embodiment, a front surface (or upper surface) and a rear surface (or lower surface) of each member may be defined based on a direction in which the image is displayed. Front and rear surfaces may oppose each other in the Z-axis direction, and normal directions of the respective front and rear surfaces may be parallel (e.g., substantially parallel) to the Z-axis direction.

The front surface of the display apparatus 1000 may be divided into a display area DA and a bezel area BZA, which is a non-display area.

The display area DA may be an area where an image is displayed. A user may view an image through the display area DA. In an embodiment, the display area DA is depicted as a rectangular shape having rounded vertices. However, this is an example only, and the display area DA may have various suitable shapes and is not limited to any one embodiment.

The bezel area BZA, which is the non-display area, may be adjacent to the display area DA. The bezel area BZA may have a set or certain color. The bezel area BZA may be around (e.g., surround) the display area DA. Accordingly, the shape of the display area DA may be defined substantially by the bezel area BZA. However, this is an example only, and the bezel area BZA may be adjacent to only one side of the display area DA, or may be omitted.

FIG. 13 is a cross-sectional view of a display module 1010 and a window member 1020 at an edge of a display apparatus 1000 according to an embodiment which is not bent.

A display apparatus 1000 may include a display module 1010 and a window member 1020 on the display module 1010.

The display module 1010 may include a configuration identical or similar to the display module 10 and display module 10′ described above. In embodiments of the same configuration, a display panel 1100 of the display module 1010 may adopt the structure of FIG. 2 or FIG. 3 as it is.

The display apparatus 1000 may include a display panel 1100, an optical functional layer 1190 on the display panel 1100, and a patterned film layer 1170 below the display panel 1100.

The display panel 1100 may display an image according to an electrical signal. For example, the display panel 1100 may be a panel which displays an image by an input data signal, and examples of the display panel 1100 may include an organic light-emitting display panel, a liquid crystal display panel, a plasma display panel, an electrophoretic display panel, an electrowetting display panel, a quantum dot light-emitting display panel, a micro light-emitting diode (LED) display panel, and/or the like. In the illustrated embodiment, an example will be described in which an organic light-emitting display panel is applied as the display panel 1100.

In an embodiment, the display area DA is depicted as a rectangular shape, but it is merely an example. For example, the display area DA may have various suitable shapes and is not limited to any one embodiment.

The display panel 1100 may be a light-emitting type or kind of display panel. For example, the display panel 1100 may be an organic light-emitting display panel and/or a quantum dot light-emitting display panel. An emission layer of the organic light-emitting display panel may include an organic light-emitting material. An emission layer of the quantum dot light-emitting display panel may include quantum dots, quantum rods, and/or the like. Hereinafter, the display panel 1100 will be described as an organic light-emitting display panel.

As an optional embodiment, the optical functional layer 1190 may be on an upper surface of the display panel 1100. The optical functional layer 1190 may include, but is not limited to, a polarizing layer, a micro lens, a prism film, and/or the like.

The optical functional layer 1190 may be attached to the upper surface of the display panel 1100. In an embodiment, a bonding layer including an adhesive material may be on a lower surface of the optical functional layer 1190. The optical functional layer 1190 may be attached to the upper surface of the display panel 1100 by the bonding layer. The bonding layer including the adhesive material may include an optically transparent bonding layer, a transparent resin bonding, and/or the like. For example, the adhesive material may include an optically transparent pressure sensitive adhesive (PSA).

As an optional embodiment, the patterned film layer 1170 may be on the lower surface of the display panel 1100. In an embodiment, the patterned film layer 1170 may include polyethylene terephthalate (PET), polyimide (PI), polycarbonate (PC), polyethylene (PE), polypropylene (PP), polysulfone (PSF), polymethyl methacrylate (PMMA), triacetyl cellulose (TAC), cycloolefin, and/or the like.

The window member 1020 may be on the display module 1010. For example, the window member 1020 may be on a front surface of the display module 1010, for example, on one surface in the Z-axis direction. In an embodiment, the window member 1020 may be in contact with the front surface of the display module 1010.

The window member 1020 may include a window 1210 and a light-shielding member 1220.

The window member 1020 may be on the display module 1010. The window 1210 may be coupled to the display module 1010 by an adhesive layer 1040. The window 1210 may protect the display module 1010 from external impacts and provide an input surface and/or a display surface to the user. The window 1210 may include a transparent material capable of projecting an image. For example, the window 1210 may include glass, sapphire, plastic (e.g., polymer), and/or the like.

Although the window 1210 is illustrated as a single layer, it is not limited thereto and may have a multi-layered structure. The multi-layered structure may be formed through a continuous process (e.g., a substantially continuous process) or a bonding process using adhesive layers. In an embodiment, the window 1210 may fully or partially have flexibility.

The window 1210 may include a light-shielding member 1220 to suppress or reduce accessory materials provided in the bezel area BZA from being visible to the user.

The light-shielding member 1220 may be an organic film including a colored organic material. For example, the light-shielding member 1220 may be a black organic film. The light-shielding member 1220 may be formed by being coated on a rear surface of the window 1210 in an area of an edge of the window 1210.

The light-shielding member 1220 may be provided in an area of the window 1210. For example, the light-shielding member 1220 may be included in a lower side of the window 1210. A lower surface of the light-shielding member 1220 may be aligned with a lower surface of the window 1210.

The light-shielding member 1220 may be formed around (e.g., to surround) a periphery of the window 1210. In an embodiment, the light-shielding member 1220 may be substantially provided in the bezel area BZA.

The adhesive layer 1040 may be between the display module 1010 and the window member 1020. The adhesive layer 1040 may include a configuration identical or similar to the aforementioned adhesive layer 40, adhesive layer 50, and adhesive layer 60. In embodiments of the same configuration, the adhesive layer 1040 may adopt the structure of FIGS. 9 to 11 as it is.

At least an area of the adhesive layer 1040 may be in contact with the window 1210, and at least another area of the adhesive layer 1040 may be in contact with the light-shielding member 1220.

In embodiments where the light-shielding member 1220 is provided below the edge of the window 1210, the adhesive layer 1040 may extend from the bottom of the window 1210 to cover an area below the light-shielding member 1220. In embodiments where the light-shielding member 1220 is included in the lower side of the window 1210, the adhesive layer 1040 may extend from the bottom of the window 1210 to an area below the light-shielding member 1220.

The adhesive layer 1040 may be in contact with both the window 1210 and the light-shielding member 1220 to ensure that the window 1210 and the light-shielding member 1220 are stably stacked on the display module 1010, thereby achieving the structural stability of the display apparatus 1000.

The adhesive layer 1040 may include a plurality of layers having different stress relaxation values, and among the plurality of layers, a layer having a relatively small stress relaxation value before curing may have an improved degree of adhesion with a configuration in contact with the layer.

In some embodiments, the adhesive layer 1040 may have a stress relaxation value, which allows for discharge of bonding bubbles and improve a bubble penetration distance. This may improve the ink-step coverage of the display apparatus 1000 and reduce a defect rate.

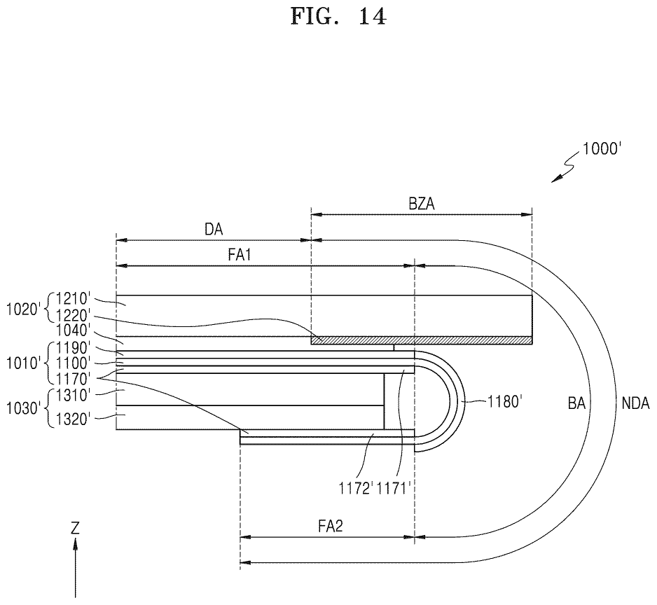

FIG. 14 is a schematic cross-sectional view of a display apparatus according to still another embodiment.

FIG. 14 is a cross-sectional view of a display module 1010′, a window member 1020′, and a lower module 1030′ at an edge of a display apparatus 1000′ according to an embodiment which is bent.

A display apparatus 1000′ may include a display module 1010′, a lower module 1030′ below the display module 1010′, and a window member 1020′ on the display module 1010′.

The display module 1010′ may include a configuration identical or similar to the display module 10 and display module 10′ described above. In embodiments of the same configuration, a display panel 1100′ of the display module 1010′ may adopt the structure of FIG. 2 or FIG. 3 as it is.

The display module 1010′ may include a display panel 1100′, an optical functional layer 1190′ on the display panel 1100′, a patterned film layer 1170′ below the display panel 1100′, and a bending protection layer 1180′ provided in a bending area.

The display panel 1100′, the patterned film layer 1170′, and the optical functional layer 1190′ may have the same configuration and effects as the display panel 1100, the patterned film layer 1170, and the optical functional layer 1190 of FIG. 13.

The display panel 1100′ may further include a flexible substrate which includes a flexible polymer material, such as polyimide. Accordingly, the display panel 1100′ may be bendable, foldable, and/or rollable.

In some embodiments, the display panel 1100′ may further include a bending area BA that is flexible and folded in one direction, and a flat area FA which is continuous to at least one side of the bending area BA and flat without being bent. The flat area FA may or may not be flexible.

In an embodiment, the bending area BA may be provided in the non-display area NDA. However, the bending area BA is not limited thereto, and may also be provided in the display area DA. The flat area FA may include a first flat area FA1 and a second flat area FA2 spaced apart from each other with the bending area BA between the first and second flat areas FA1 and FA2. The first flat area FA1 may be provided in the display area DA and at least a portion of the non-display area NDA. The bending area BA may be continuous to the first flat area FA1 and may be provided in the non-display area NDA. The second flat area FA2 may be continuous to the bending area BA and may be provided in the non-display area NDA. The bending area BA and the second flat area FA2 may be provided in at least a portion of a protruding area of the non-display area NDA.

In the bending area BA, the display panel 1100 may be bent having a curvature in a downward direction, e.g., in an opposite direction to a display surface. The bending area BA may have a constant (e.g., substantially constant) radius of curvature, but is not limited thereto and may have a different radius of curvature for each section. For example, the display panel 1100′ may have a semicircular shape or a semi-elliptical shape in the bending area BA.

The patterned film layer 1170′ may be on a lower surface of the display panel 1100′. The patterned film layer 1170′ may be between the display panel 1100′ and an upper bonding layer to suppress or reduce contact of the display panel 1100′ with the lower module 1030′ arranged below the display panel 1100′.

The patterned film layer 1170′ may include a first patterned film 1171′ and a second patterned film 1172′ which are spaced apart from each other along a direction perpendicular (e.g., substantially perpendicular) to the Z-axis. The patterned film layer 1170′ may be provided in at least a portion of the flat area FA. The patterned film layer 1170′ may not be provided in the bending area BA. For example, the first patterned film 1171′ may be provided in at least a portion of the first flat area FA1, and the second patterned film 1172′ may be provided in at least a portion of the second flat area FA2. Accordingly, an inner surface of the display panel 1100′ may be exposed toward a cover panel 1310′.

The bending protection layer 1180′ may be on a portion of the display panel 1100′. In an embodiment, the bending protection layer 1180′ may be on the bending area of the display panel 1100′. However, it is not limited to this, and the bending protection layer 1180′ may also be on a portion of the non-display area NDA in addition to the bending area BA.

The bending protection layer 1180′ may include a polymer compound, such as polyimide, acrylate, and/or epoxy. The bending protection layer 1180′ may minimize or reduce an occurrence of cracks due to stress, which is applied to a substrate 1110′ when the display panel 1100′ is bent, and block or reduce the propagation of the cracks. Accordingly, the display module 1010′ may achieve improved durability.

The lower module 1030′ may be below the display module 1010′. For example, the lower module 1030′ may be on a rear surface of the display module 1010′, for example, on an opposite surface in the Z-axis direction. In an embodiment, the lower module 1030′ may be in contact with the rear surface of the display module 1010′.

The lower module 1030′ may be between portions of the display module 1010′ in the Z-axis direction in the bent state of the display module 1010′. For example, the lower module 1030′ may be between the first patterned film 1171′ and the second patterned film 1172′ in the Z-axis direction.

The lower module 1030′ may include a cover panel 1310′ and a cover spacer 1320′.

The cover panel 1310′ may be on a lower surface of the first patterned film 1171′. The cover panel 1310′ may be attached to the display panel 1100′ or the patterned film layer 1170′ below the display panel 1100′ by an upper bonding layer, which is included in the cover panel 1310′.

The cover panel 1310′ may perform functions, such as heat dissipation, electromagnetic interference shielding, buffering, and/or strength reinforcement.

The cover spacer 1320′ may control a degree of bending (or curvature) of the display panel 1100′ by maintaining a constant (e.g., substantially constant) distance between the cover panel 1310′ and the display panel 1100′ when the display panel 1100′ is bent.

In an embodiment, the cover spacer 1320′ may include a material, which is suitable for the design conditions of the display panel 1100′, among elastic materials and/or materials capable of performing a support function. For example, the cover spacer 1320′ may include a thermoplastic elastomer, polystyrene, polyolefin, polyurethane thermoplastic elastomer, and/or the like. As another example, the cover spacer 1320′may include polycarbonate (PC), polyimide (PI), polyethylene terephthalate (PET), and/or the like.

A window 1210′ and a light-shielding member 1220′ included in the window member 1020′ may have the same configuration and effects as the window 1210 and the light-shielding member 1220 of FIG. 13.

The window 1210′ may be coupled to the display module 1010′ by an adhesive layer 1040′. At least an area of the adhesive layer 1040′ may be in contact with the window 1210′, and at least another area of the adhesive layer 1040′ may be in contact with the light-shielding member 1220′.

The adhesive layer 1040′ may be between the display module 1010′ and the window member 1020′. The adhesive layer 1040′ may include a configuration identical or similar to the aforementioned adhesive layer 40, adhesive layer 50, and adhesive layer 60. In embodiments of the same configuration, the adhesive layer 1040′ may adopt the structure of FIGS. 9 to 11 as it is.

In embodiments where the light-shielding member 1220′ is below an edge of the window 1210′, the adhesive layer 1040′ may extend from the bottom of the window 1210′ to cover an area below the light-shielding member 1220′. In embodiments where the light-shielding member 1220′ is included in the lower side of the window 1210′, the adhesive layer 1040′ may extend from the bottom of the window 1210′ to an area below the light-shielding member 1220′.

The adhesive layer 1040′ may be in contact with both the window 1210′ and the light-shielding member 1220′ to ensure that the window 1210′ and the light-shielding member 1220′ are stably stacked on the display module 1010′, thereby achieving the structural stability of the display apparatus 1000′.

The adhesive layer 1040′ may include at least one layer having a stress relaxation value of 0.01 to 0.07 before curing and a stress relaxation value of 0.3 to 0.5 after curing, and another layer having a greater stress relaxation value before and after curing than the at least one layer. By including a layer having a relatively low stress relaxation value, the display module 1010′ may be easily formed into a curved shape.

The adhesive layer 1040′ may include a plurality of layers having different stress relaxation values, and among the plurality of layers, a layer having a relatively small stress relaxation value before curing may have an improved degree of adhesion with a configuration in contact with the layer.

In some embodiments, the adhesive layer 1040′ may be formed to have a stress relaxation value, which allows for discharge of bonding bubbles and improves a bubble penetration distance. This may improve the ink-step coverage of the display apparatus 1000 and reduce a defect rate.

Each of the embodiments described above may be implemented independently, but in embodiments, the structure of each embodiment may be applied in combination to other embodiments.

As such, the subject matter of the present disclosure has been described with reference to the embodiments illustrated in the drawings, but those are merely examples, and it will be understood by those skilled in the art that various suitable modifications and variations of the embodiments may be made. Therefore, the true technical protection scope of the disclosure should be defined by the scope of the appended claims and equivalents thereof.

The specific executions described with respect to embodiments herein are merely examples, and do not limit the scope of the disclosure in any way. Furthermore, unless otherwise indicated by terms, such as “essential,” “important,” and the like, a component may not be a necessary component for the application of the disclosure.

In the specification (and, for example, in the claims) of the embodiment, the use of the term “the” and similar referential terms may refer to both the singular and the plural. Also, when a range is described in an embodiment, an embodiment to which individual values belonging to the range are applied is included (unless otherwise described contrarily), and each individual value constituting the range is described in the detailed description. Finally, the processes of methods according to embodiments may be performed in any suitable order unless otherwise explicitly indicated herein or otherwise clearly contradicted by context. The embodiments are not necessarily limited by the order of processes described above. The use of any examples or illustrative terms in an embodiment is merely to describe the embodiment in more detail, and unless limited by the claims, the scope of the embodiment is not limited by the examples or illustrative terms. Further, it will be understood by those skilled in the art that various suitable modifications, combinations and changes may be made depending on design conditions and factors within the scope of the appended claims or their equivalents.

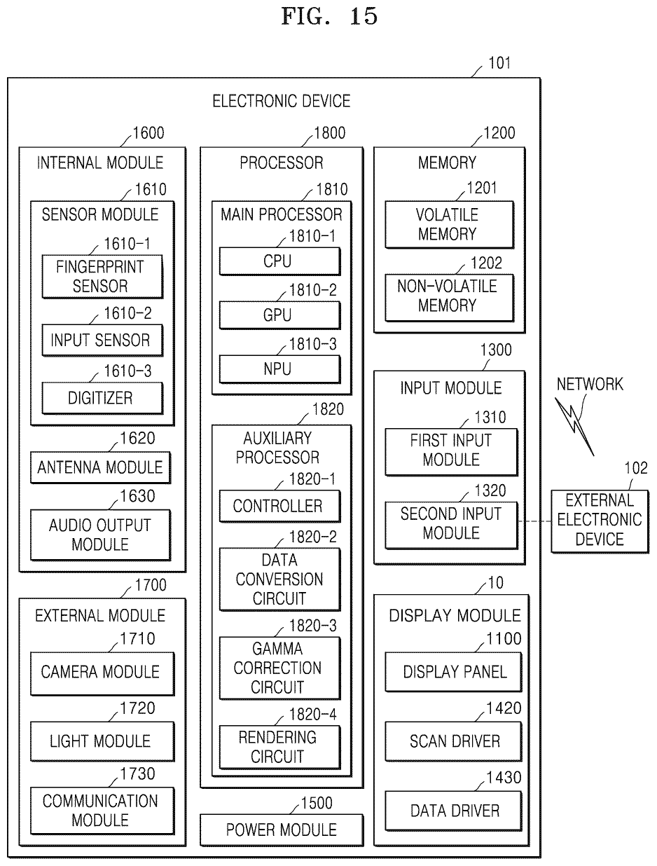

FIG. 15 is a block diagram of an electronic device according to embodiments.

An electronic device 101 may output various suitable types or kinds of information through a display module 10 in an operating system. In embodiments where a processor 1800 executes an application stored in a memory 1200, the display module 10 may provide application information to a user through a display panel 1100.

The processor 1800 may obtain external input through an input module 1300 and/or a sensor module 1610 and execute an application corresponding to the external input. For example, when the user selects a camera icon displayed on the display panel 1100, the processor 1800 may obtain user input through an input sensor 1610-2 and activate a camera module 1710. The processor 1800 may transmit image data, which corresponds to a photographed image acquired through the camera module 1710, to the display module 10. The display module 10 may display an image corresponding to the photographed image through the display panel 1100.

As another example, in embodiments where personal information authentication is performed in the display module 10, a fingerprint sensor 1610-1 may acquire input fingerprint information as input data. The processor 1800 may compare the input data acquired through the fingerprint sensor 1610-1 with authentication data stored in the memory 1200, and execute an application based on a result of the comparison. The display module 10 may display information executed according to a logic of the application through the display panel 1100.

As another example, in embodiments where a music streaming icon displayed on the display module 10 is selected, the processor 1800 may obtain user input through the input sensor 1610-2 and activate a music streaming application stored in the memory 1200. In embodiments where a music execution command is input in the music streaming application, the processor 1800 may activate an audio output module 1630 to provide the user with audio information corresponding to the music execution command.

So far, the operation of the electronic device 101 has been briefly described. Hereinafter, the configuration of the electronic device 101 will be described in more detail. Some of respective components of the electronic device 101 to be described below may be provided as one integrated component, and one component may be provided by being separated into two or more components.

Referring to FIG. 15, the electronic device 101 may communicate with an external electronic device 102 via a network (e.g., a short-range wireless communication network and/or a long-range wireless communication network). According to an embodiment, the electronic device 101 may include a processor 1800, a memory 1200, an input module 1300, a display module 10, a power module 1500, an internal module 1600, and an external module 1700. According to an embodiment, the electronic device 101 may exclude at least one of the components, or may additionally include at least one component. In an embodiment, some of the components described above (e.g., the sensor module 1610, the antenna module 1620, and/or the audio output module 1630) may be integrated into another component (e.g., the display module 10).

The processor 1800 may execute software to control at least another component (e.g., a hardware and/or software component) of the electronic device 101 connected to the processor 1800, and perform various suitable data processing and/or operations. According to an embodiment, as at least some of the data processing and/or operations, the processor 1800 may store commands and/or data received from another component (e.g., the input module 1300, the sensor module 1610, and/or a communication module 1730) in a volatile memory 1201, process the commands and/or data stored in the volatile memory 1201, and store resultant data in a non-volatile memory 1202.

The processor 1800 may include a main processor 1810 and an auxiliary processor 1820. The main processor 1810 may include one or more of a central processing unit (CPU) 1810-1 or an application processor (AP). The main processor 1810 may further include one or more of a graphics processing unit (GPU) 1810-2, a communication processor (CP), or an image signal processor (ISP). The main processor 1810 may further include a neural processing unit (NPU) 1810-3. The NPU may be a processor specialized in processing an artificial intelligence model, and the artificial intelligence model may be created through machine learning. The artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the networks, but is not limited to the examples described above. The artificial intelligence model may additionally or alternatively include a software structure in addition to a hardware structure. At least two of the processing units and processors described above may be implemented as a single integrated configuration (e.g., a single chip) or the respective processing units and processors may be implemented as independent components (e.g., a plurality of chips).

The auxiliary processor 1820 may include a controller 1820-1. The controller 1820-1 may include an interface conversion circuit and a timing control circuit. The controller 1820-1 may receive an image signal from the main processor 1810, and output image data by converting a data format of the image signal to comply with an interface specification with the display module 10. The controller 1820-1 may output various suitable control signals, which are utilized or required for operation of the display module 10.

The auxiliary processor 1820 may further include a data conversion circuit 1820-2, a gamma correction circuit 1820-3, a rendering circuit 1820-4, and the like. The data conversion circuit 1820-2 may receive image data from the controller 1820-1, and compensate for the image data so that the image is displayed at a suitable or desired brightness according to the characteristics of the electronic device 101 and/or user settings, and/or may convert the image data to reduce power consumption and/or compensate for afterimages. The gamma correction circuit 1820-3 may convert image data and/or a gamma reference voltage, so that an image displayed on the electronic device 101 has suitable or desired gamma characteristics. The rendering circuit 1820-4 may receive image data from the controller 1820-1 and render the image data by taking into account a pixel arrangement of the display panel 1100 applied to the electronic device 101. At least one of the data conversion circuit 1820-2, the gamma correction circuit 1820-3, or the rendering circuit 1820-4 may be integrated into another component (e.g., the main processor 1810 and/or the controller 1820-1). At least one of the data conversion circuit 1820-2, the gamma correction circuit 1820-3, or the rendering circuit 1820-4 may be integrated into a data driver 1430 to be described herein.

The memory 1200 may store various suitable kinds of data used by at least one component of the electronic device 101 (e.g., the processor 1800 and/or the sensor module 1610) and input data and/or output data for commands related to the various suitable kinds of data. The memory 1200 may include at least one of a volatile memory 1201 or a non-volatile memory 1202.

The input module 1300 may receive commands and/or data to be used in a component of the electronic device 101 (e.g., the processor 1800, the sensor module 1610, and/or the audio output module 1630) from the exterior of the electronic device 101 (e.g., the user and/or the external electronic device 102).

The input module 1300 may include a first input module 1310 into which a command and/or data is input from the user, and a second input module 1320 into which a command and/or data is input from the external electronic device 102. The first input module 1310 may include a microphone, a mouse, a keyboard, keys (e.g., buttons), and/or a pen (e.g., a passive pen and/or an active pen). The second input module 1320 may support a designated protocol that may be connected wiredly and/or wirelessly with the external electronic device 102. According to an embodiment, the second input module 1320 may include a high-definition multimedia interface (HDMI), a universal serial bus (USB) interface, a secure digital (SD) card interface, and/or an audio interface. The second input module 1320 may include a connector that may be physically connected to the external electronic device 102, for example, an HDMI connector, a USB connector, an SD card connector, and/or an audio connector (e.g., a headset connector).

The display module 10 may provide information visually to the user. The display module 10 may include a display panel 1100, a scan driver 1420, and a data driver 1430. The display module 10 may further include a window to protect the display panel 1100, a chassis, and a bracket.

The display panel 1100 may include a liquid crystal display panel, an organic light-emitting display panel, and/or an inorganic light-emitting display panel, and the type or kind of the display panel 1100 is not particularly limited. The display panel 1100 may be of a rigid type or kind or a flexible type or kind which is rollable and/or foldable. The display module 10 may further include a supporter which supports the display module 10, a bracket, and/or a heat dissipation member.

The scan driver 1420 may be mounted as a drive chip in the display panel 1100. In some embodiments, the scan driver 1420 may be integrated into the display panel 1100. For example, the scan driver 1420 may include an amorphous silicon TFT gate driver circuit (ASG), a low temperature polycrystalline silicon (LTPS) TFT gate driver circuit, or an oxide semiconductor TFT gate driver circuit (OSG), which is embedded in the display panel 1100. The scan driver 1420 may receive a control signal from the controller 1820-1, and output scan signals to the display panel 1100, in response to the control signal.

The display panel 1100 may further include an emission driver. The emission driver may output an emission control signal to the display panel 1100, in response to a control signal received from the controller 1820-1. The emission driver may be formed separately from the scan driver 1420 or may be integrated into the scan driver 1420.

The data driver 1430 may receive a control signal from the controller 1820-1, convert image data into analog voltages (e.g., data voltages), in response to the control signal, and output the data voltages to the display panel 1100.

The data driver 1430 may be integrated into another component (e.g., the controller 1820-1). The functions of the interface conversion circuit and the timing control circuit of the controller 1820-1 may also be integrated into the data driver 1430.

The display module 10 may further include an emission driver, a voltage generation circuit, and/or the like. The voltage generation circuit may output various suitable voltages utilized or required to drive the display panel 1100.

The power module 1500 may supply power to respective components of the electronic device 101. The power module 1500 may include a battery that charges a power voltage. The battery may include a non-rechargeable primary battery, a rechargeable secondary battery, and/or a fuel cell. The power module 1500 may include a power management integrated circuit (PMIC). The PMIC may supply power optimized or improved for each of the modules described above and modules described herein.

The power module 1500 may include a wireless power transmission and reception member electrically connected to the battery. The wireless power transmission and reception member may include a plurality of coil-shaped antenna radiators.

The electronic device 101 may further include an internal module 1600 and an external module 1700. The internal module 1600 may include a sensor module 1610, an antenna module 1620, and an audio output module 1630. The external module 1700 may include a camera module 1710, a light module 1720, and a communication module 1730.

The sensor module 1610 may detect input by the user's body and/or input by a pen of the first input module 1310, and generate an electric signal and/or data value in response to the input. The sensor module 1610 may include at least one of a fingerprint sensor 1610-1, an input sensor 1610-2, or a digitizer 1610-3.

The fingerprint sensor 1610-1 may generate a data value corresponding to the user's fingerprint. The fingerprint sensor 1610-1 may include any one of an optical fingerprint sensor or a capacitive fingerprint sensor.

The input sensor 1610-2 may generate a data value corresponding to coordinate information about input by the user's body or input by the pen. The input sensor 1610-2 may generate a data value based on the change in capacitance due to input. The input sensor 1610-2 may detect input by a passive pen and/or transmit and receive data to and from an active pen.

The input sensor 1610-2 may also measure a bio-signal, such as blood pressure, moisture, and/or body fat. For example, when the user does not move for a set or certain period of time while touching a portion of his or her body to a sensor layer and/or sensing panel, the input sensor 1610-2 may detect a bio-signal based on a change in electric field caused by the portion of his or her body, and output information desired by the user to the display module 10.

The digitizer 1610-3 may generate a data value corresponding to coordinate information input by the pen. The digitizer 1610-3 may generate a data value based on an electromagnetic change by input. The digitizer 1610-3 may detect input by the passive pen and/or transmit and receive data to and from the active pen.

At least one of the fingerprint sensor 1610-1, the input sensor 1610-2, or the digitizer 1610-3 may be implemented as a sensor layer on the display panel 1100 through a continuous (e.g., substantially continuous) process. The fingerprint sensor 1610-1, the input sensor 1610-2, and the digitizer 1610-3 may be on the display panel 1100, and any one of the fingerprint sensor 1610-1, the input sensor 1610-2, or the digitizer 1610-3, for example, the digitizer 1610-3, may be below the display panel 1100.

At least two of the fingerprint sensor 1610-1, the input sensor 1610-2, or the digitizer 1610-3 may be integrated into a single sensing panel through the same process. In case of being integrated into a single sensing panel, the sensing panel may be between the display panel 1100 and a window on the display panel 1100. According to an embodiment, the sensing panel may be on the window, and the location of the sensing panel is not particularly limited.

At least one of the fingerprint sensor 1610-1, the input sensor 1610-2, or the digitizer 1610-3 may be embedded in the display panel 1100. For example, at least one of the fingerprint sensor 1610-1, the input sensor 1610-2, or the digitizer 1610-3 may be formed concurrently (e.g., simultaneously) through a process of forming elements (e.g., light-emitting elements, transistors, and/or the like) included in the display panel 1100.

In some embodiments, the sensor module 1610 may generate an electrical signal and/or data value corresponding to an internal and/or external state of the electronic device 101. The sensor module 1610 may further include, for example, a gesture sensor, a gyro sensor, an air pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 1620 may include one or more antennas to transmit signals and/or power to and/or receive signals and/or power from the exterior. According to an embodiment, the communication module 1730 may transmit a signal to an external electronic device and/or receive a signal from the external electronic device through an antenna suitable for a communication method. An antenna pattern of the antenna module 1620 may be integrated into one component of the display module 10 (e.g., display panel 1100) and/or the input sensor 1610-2.

The audio output module 1630 may be a device to output audio signals to the outside of the electronic device 101, and may include, for example, a speaker used for general purposes, such as such as playing multimedia and/or playing recordings, and a receiver used exclusively for incoming calls. According to an embodiment, the receiver may be formed integrally with or separately from the speaker. An audio output pattern of the audio output module 1630 may also be integrated into the display module 10.

The camera module 1710 may capture still images and/or moving images (videos). According to an embodiment, the camera module 1710 may include one or more lenses, image sensors, and/or image signal processors. The camera module 1710 may further include an infrared camera which may measure presence or absence of a user, the user's location, the user's gaze, and/or the like.

The light module 1720 may provide light. The light module 1720 may include a light-emitting diode and/or a xenon lamp. The light module 1720 may operate in conjunction with the camera module 1710 or independently.

The communication module 1730 may support establishment of a wired and/or wireless communication channel between the electronic device 101 and the external electronic device 102, and performance of communication through the established communication channel. The communication module 1730 may include one or all of a wireless communication module, such as a cellular communication module, a short-range wireless communication module, and/or a global navigation satellite system (GNSS) communication module, and a wired communication module, such as a local area network (LAN) communication module, and/or a power line communication module. The communication module 1730 may communicate with the external electronic device 102 via a short-range communication network, such as Bluetooth, WiFi direct, and/or infrared data association (IrDA), and/or a long-range communication network, such as a cellular network, the Internet, and/or a computer network (e.g., a LAN and/or WAN). The various suitable types or kinds of communication modules 1730 described above may be implemented as one chip or as separate chips.

The input module 1300, the sensor module 1610, the camera module 1710, and/or the like may be used to control the operation of the display module 10 in conjunction with the processor 1800.

The processor 1800 may output a command and/or data to the display module 10, the audio output module 1630, the camera module 1710, and/or light module 1720 based on input data received from the input module 1300. For example, the processor 1800 may generate image data in response to input data received through a mouse, an active pen, and/or the like and output the generated image data to the display module 10, and/or may generate command data in response to the input data and output the generated command data to the camera module 1710 or the light module 1720. In embodiments where no input data is received from the input module 1300 for a set or certain period of time, the processor 1800 may switch an operation mode of the electronic device 101 to a low-power mode or sleep mode to reduce power consumption of the electronic device 101.

The processor 1800 may output a command and/or data to the display module 10, the audio output module 1630, the camera module 1710, and/or the light module 1720 based on sensing data received from the sensor module 1610. For example, the processor 1800 may compare authentication data applied by the fingerprint sensor 1610-1 with authentication data stored in the memory 1200, and execute an application based on a result of the comparison. The processor 1800 may execute a command and/or output corresponding image data to the display module 10 based on sensing data detected by the input sensor 1610-2 or the digitizer 1610-3. In embodiments where a temperature sensor is included in the sensor module 1610, the processor 1800 may receive temperature data on a measured temperature from the sensor module 1610, and further perform brightness correction and/or the like on image data based on the temperature data.

The processor 1800 may receive measurement data on the presence or absence of a user, the user's location, the user's gaze, and/or the like from the camera module 1710. The processor 1800 may further perform brightness correction and/or the like on image data based on the measurement data. For example, the processor 1800 which has determined the presence or absence of the user through input from the camera module 1710 may output image data, which has brightness corrected through the data conversion circuit 1820-2 and/or the gamma correction circuit 1820-3, to the display module 10.

Some of the components may be connected to each other through a communication method between peripheral devices, such as a bus, general purpose input/output (GPIO), serial peripheral interface (SPI), mobile industry processor interface (MIPI), and/or ultra path interconnect (UPI) link, to exchange signals (e.g., commands or data) with each other. The processor 1800 may communicate with the display module 10 through a mutually agreed interface, and for example, may use any one of the aforementioned communication methods, and the communication method is not limited to the aforementioned communication methods.

The electronic device 101 according to various embodiments disclosed herein may be various suitable types or kinds of devices. The electronic device 101 may include, for example, at least one of a portable communication device (e.g., a smartphone), a computer device, a portable multimedia device, a portable medical device, a camera, a wearable device, or a home appliance device. The electronic device 101 according to an embodiment is not limited to the devices described above.

A display apparatus and a method of manufacturing the display apparatus according to one or more embodiments may reduce a defect rate of a product.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the drawings, it will be understood by those of ordinary skill in the art that various suitable changes in form and details may be made therein without departing from the spirit and scope of the present disclosure as defined by the following claims and equivalents thereof.

What is claimed is:

1. A display apparatus comprising;
a display module that emits visible light;
a window member opposite to one surface of the display module; and
an adhesive layer between the display module and the window member,
wherein the adhesive layer is formed by:
curing an adhesive comprising at least a high-molecular weight acrylic polymer having a first weight-average molecular weight of at least 700,000 and a low-molecular weight acrylic polymer having a second weight-average molecular weight of less than 500,000,
the adhesive layer has a stress relaxation value of 0.01 to 0.07 before curing, and a stress relaxation value of 0.30 to 0.50 after curing, and
an amount of the high-molecular weight acrylic polymer is at least 30 parts by weight, with respect to 100 parts by weight of a sum of an amount of the high-molecular weight acrylic polymer and an amount of the low-molecular weight acrylic polymer.

2. The display apparatus of claim 1, wherein:
the first weight-average molecular weight is 700,000 to 3,000,000.

3. The display apparatus of claim 1, wherein:
the second weight-average molecular weight is 100,000 to 300,000.

4. The display apparatus of claim 1, wherein:
the stress relaxation value is measured at 70° C.

5. The display apparatus of claim 1, wherein:
the adhesive layer comprises a permeable polymer which allows at least some of the visible light to penetrate therethrough.

6. The display apparatus of claim 1, wherein:
the adhesive layer comprises a first adhesive layer and a second adhesive layer having different stress relaxation values.

7. The display apparatus of claim 6, wherein:
the second adhesive layer has a stress relaxation value of 0.4 to 0.6 before and after curing.

8. The display apparatus of claim 6, wherein:
the adhesive layer further comprises a third adhesive layer having a smaller stress relaxation value than the second adhesive layer, and
the second adhesive layer is between the first adhesive layer and the third adhesive layer.

9. The display apparatus of claim 8, wherein:
the first adhesive layer and/or the third adhesive layer has a stress relaxation value of 0.01 to 0.07 before curing, and a stress relaxation value of 0.30 to 0.50 after curing.

10. The display apparatus of claim 6, wherein:
the first adhesive layer has a creep value of at least 4% at 50° C., a modulus of 0.04 MPa to 0.70 MPa at 25° C., and adhesion of at least 0.5 kgf/in, and
the second adhesive layer has a creep value of at least 4% at 50° C. and a modulus of 0.04 MPa to 0.70 MPa at 25° C.

11. A display apparatus comprising:
a display module that emits visible light;
a window member opposite to one surface of the display module; and
an adhesive layer between the display module and the window member,
wherein the adhesive layer has a stress relaxation value of 0.01 to 0.07 before curing, a stress relaxation value of 0.30 to 0.50 after curing, a creep value of at least 4% at 50° C., and a modulus of 0.04 MPa to 0.70 MPa at 25° C.

12. The display apparatus of claim 11, wherein
the adhesive layer is formed by curing an adhesive comprising at least a high-molecular weight acrylic polymer having a first weight-average molecular weight of at least 700,000 and a low-molecular weight acrylic polymer having a second weight-average molecular weight of less than 500,000, and
an amount of the high-molecular weight acrylic polymer is at least 30 parts by weight, with respect to 100 parts by weight of a sum of an amount of the high-molecular weight acrylic polymer and an amount of the low-molecular weight acrylic polymer.

13. The display apparatus of claim 12, wherein:
the first weight-average molecular weight is 700,000 to 3,000,000.

14. The display apparatus of claim 12, wherein:
the second weight-average molecular weight is 100,000 to 300,000.

15. The display apparatus of claim 11, wherein:
the adhesive layer comprises a permeable polymer which allows at least some of the visible light to penetrate therethrough.

16. The display apparatus of claim 11, wherein:
the adhesive layer comprises a first adhesive layer and a second adhesive layer having different stress relaxation values.

17. The display apparatus of claim 16, wherein:
the second adhesive layer has a stress relaxation value of 0.4 to 0.6 before and after curing.

18. The display apparatus of claim 16, wherein:
the adhesive layer further comprises a third adhesive layer having a smaller stress relaxation value than the second adhesive layer, and
the second adhesive layer is between the first adhesive layer and the third adhesive layer.

19. The display apparatus of claim 18, wherein:
the first adhesive layer and/or the third adhesive layer has a stress relaxation value of 0.01 to 0.07 before curing, and a stress relaxation value of 0.30 to 0.50 after curing.

20. An electronic device comprising:
a controller configured to generate a scan input signal;
a power module configured to generate a scan input voltage;
a display module comprising a display panel divided into a display area in which a pixel circuit is provided and a non-display area surrounding the display area, wherein the display module emits visible light;
a window member opposite to one surface of the display module;
an adhesive layer between the display module and the window member; and
a scan driver provided in the non-display area, and configured to receive the scan input signal and the scan input voltage and output a scan signal to the pixel circuit;
wherein the adhesive layer is formed by:
curing an adhesive comprising at least a high-molecular weight acrylic polymer having a first weight-average molecular weight of at least 700,000 and a low-molecular weight acrylic polymer having a second weight-average molecular weight of less than 500,000,
the adhesive layer has a stress relaxation value of 0.01 to 0.07 before curing, and a stress relaxation value of 0.30 to 0.50 after curing, and
an amount of the high-molecular weight acrylic polymer is at least 30 parts by weight, with respect to 100 parts by weight of a sum of an amount of the high-molecular weight acrylic polymer and an amount of the low-molecular weight acrylic polymer.
